(19) United States
(12) Patent Application Publication
(10) Pub. No.: US 2013/0009630 A1
(43) Pub. Date: Jan. 10, 2013

(54) MAGNETIC DETECTION DEVICE, MAGNETIC SENSOR INCLUDING THE SAME, AND METHOD FOR MANUFACTURING MAGNETIC DETECTION DEVICE

(75) Inventors: Fumihito KOIKE, Niigata-ken (JP); Kota ASATSUMA, Niigata-ken (JP); Kazuya OMINATO, Niigata-ken (JP)

(73) Assignee: ALPS ELECTRIC CO., LTD., Tokyo (JP)

(21) Appl. No.: 13/464,733

(22) Filed: May 4, 2012

(30) Foreign Application Priority Data
Jul. 4, 2011 (JP) 2011-147941

(51) Int. Cl. G01R 33/10; C23C 14/34

(52) U.S. Cl. 324/200; 204/192.15

(57) ABSTRACT

A magnetic detection device includes a layered film including a self-pinned magnetic layer, a free magnetic layer, a nonmagnetic material layer disposed between the pinned magnetic layer and the free magnetic layer, and a top capping layer. The pinned magnetic layer includes a first magnetic layer, a second magnetic layer, and a nonmagnetic intermediate layer disposed therebetween. A first magnetization of the first magnetic layer is pinned in antiparallel with a second magnetization of the second magnetic layer. The capping layer is formed of tantalum, and an as-deposited thickness of the capping layer is 55 Å or more.

### CLAIM OF PRIORITY

This application claims benefit of Japanese Patent Application No. 2011-147941 filed on Jul. 4, 2011, which is hereby incorporated by reference.

### BACKGROUND OF THE INVENTION

1. Field of the Invention

The present invention relates to self-pinned magnetic detection devices.

2. Description of the Related Art

A typical method of the related art that uses an antiferromagnetic layer to pin the magnetization of a pinned magnetic layer with an exchange coupling field (Hex) involves field annealing (heat treatment) in a vacuum to control the crystal orientation of the antiferromagnetic layer and to reduce magnetization dispersion (to facilitate formation of a single magnetic domain) of the pinned magnetic layer. Vacuum annealing, which causes little oxidation, has little effect on properties such as the rate of change in resistance (ΔMR) even if the thickness of a tantalum capping layer is reduced to about 30 to 50 Å.

A field annealing apparatus, however, is expensive and requires an extended period of time for vacuum annealing.

U.S. Pat. Nos. 7,019,949 B2 and 7,196,878 B2 disclose magnetic detection devices including a self-pinned magnetic layer without an antiferromagnetic layer. In these publications, the thickness of a tantalum capping layer is set to 40 Å.

A self-pinned magnetic detection device requires no field annealing, although it has to be annealed without a magnetic field so that the properties thereof do not vary after a high-temperature process following the deposition of the magnetic detection device in the process of manufacturing a magnetic sensor or after the use of the magnetic sensor at high temperatures. The annealing apparatus used therefor is usually inexpensive and requires a short period of time for annealing. An experiment conducted this time, however, has revealed that a tantalum capping layer having a thickness of about 40 Å, as in the above publications, has a problem in inhibiting property degradation.

Japanese Unexamined Patent Application Publication No. 2008-306112 discloses a magnetic detection device including a self-pinned magnetic layer and a ruthenium capping layer. It also discloses a comparative example that uses a tantalum capping layer, although the thickness thereof is not disclosed. Assuming that the tantalum capping layer has the same thickness as the ruthenium capping layer described in the Examples, the thickness is 30 Å. As with a tantalum capping layer having a thickness of 40 Å, a tantalum capping layer having a thickness of 30 Å has a problem in inhibiting property degradation.

Japanese Unexamined Patent Application Publication No. 2009-180604 discloses a magnetic detection device including a self-pinned magnetic layer, although the material and thickness of a capping layer are not disclosed.

### SUMMARY OF THE INVENTION

The present invention provides a magnetic detection device including a self-pinned magnetic layer and a tantalum capping layer having an appropriate thickness and that provides superior soft magnetic properties more stably than in the related art, a magnetic sensor including such magnetic detection devices, and a method for manufacturing such a magnetic detection device.

An aspect of the present invention provides a magnetic detection device including a layered film including a self-pinned magnetic layer, a free magnetic layer, a nonmagnetic material layer disposed therebetween, and a top capping layer. The pinned magnetic layer includes a first magnetic layer, a second magnetic layer, and a nonmagnetic intermediate layer disposed therebetween. A first magnetization of the first magnetic layer is pinned in antiparallel with a second magnetization of the second magnetic layer. The capping layer is formed of tantalum, and an as-deposited thickness of the capping layer is 55 Å or more.

Another aspect of the present invention provides a method for manufacturing a magnetic detection device including a layered film including a pinned magnetic layer, a free magnetic layer, and a nonmagnetic material layer disposed therebetween. The method includes forming a self-pinned magnetic layer by forming a first magnetic layer and a second magnetic layer with a nonmagnetic intermediate layer therebetween; forming a top capping layer formed of tantalum; and performing annealing without a magnetic field in air or an inert gas flow. A first magnetization of the first magnetic layer is pinned in antiparallel with a second magnetization of the second magnetic layer. An as-deposited thickness of the capping layer is 55 Å or more.

In the above aspects, the as-deposited thickness of the tantalum capping layer in the magnetic detection device including the self-pinned magnetic layer is set to 55 Å or more based on the experimental results described later. The lower limit of the thickness of the tantalum capping layer is set to 55 Å because a thickness of less than 55 Å results in a sharply increased interlayer coupling field Hin between the free magnetic layer and the pinned magnetic layer and therefore a sharply decreased ΔMR. The upper limit of the thickness of the tantalum capping layer is not specified. As the thickness of the tantalum capping layer is extremely increased, however, more current is shunted into the tantalum capping layer (shunt loss), thus decreasing ΔMR. By adjusting the thickness of the tantalum capping layer, ΔMR can be adjusted without degrading the reliability of other magnetic properties.

Thus, according to the above aspects, the magnetic detection device including the self-pinned magnetic layer stably provides superior soft magnetic properties.

The thickness of the tantalum capping layer, which is set to 55 Å or more in the above aspects, is the as-deposited thickness. After post-deposition annealing, the thickness of the tantalum capping layer becomes larger than the as-deposited thickness as a result of partial oxidation. The as-deposited thickness of the tantalum capping layer can be estimated by analyzing the annealed condition, as shown in the experimental results described later.

In the above aspects, the as-deposited thickness of the capping layer is preferably 100 Å or less. It has turned out that a tantalum capping layer having a thickness of 100 Å or less limits a decrease in ΔMR after field-free annealing to about 0.5% as compared with the as-deposited ΔMR of a magnetic detection device including a tantalum capping layer having an as-deposited thickness of 30 Å. In addition, the capping layer preferably includes a portion formed of metallic tantalum adjacent to the free magnetic layer.

In the above aspects, the thickness of the capping layer is preferably 70 to 100 Å. By shifting the lower limit of the thickness of the tantalum capping layer from 55 Å to 70 Å, superior soft magnetic properties can be stably provided even if the as-deposited thickness deviates slightly from the target thickness.

Another aspect of the present invention provides a magnetic sensor including a substrate and a plurality of magnetic detection devices described above that are arranged on the substrate. The plurality of magnetic detection devices have different sensitive axis directions.

With the self-pinned magnetic detection devices described above, the magnetic sensor according to the above aspect stably provides superior output characteristics for various applications.

### BRIEF DESCRIPTION OF THE DRAWINGS

FIG. 1 is a partial enlarged cross-sectional view of a magnetic detection device according to an embodiment of the present invention;

FIGS. 2A to 2C are partial longitudinal sectional views showing the positional relationship between the magnetic detection device shown in FIG. 1 and hard bias layers connected to the magnetic detection device;

FIG. 3 is a circuit diagram of a magnetic sensor according to the embodiment of the present invention;

FIGS. 4A and 4B are plan views, each illustrating a step of a method for manufacturing the magnetic sensor according to the embodiment of the present invention;

FIGS. 5A to 5D are graphs showing the as-deposited hysteresis loops of magnetic detection devices including tantalum capping layers having varying thicknesses;

FIGS. 5E to 5H are graphs showing the hysteresis loops after annealing of magnetic detection devices including tantalum capping layers having varying thicknesses;

FIGS. 5I and 5J are graphs showing the hysteresis loops of the same magnetic detection devices as those in FIGS. 5E and 5F, respectively, over a larger range of external magnetic field than FIGS. 5E and 5F;

FIG. 6 is a graph showing the relationship between the thickness of a tantalum capping layer and the ΔMR as-deposited and after annealing;

FIG. 7 shows the same graph as FIG. 6 with the vertical axis extended;

FIG. 8 is a graph showing the relationship between the thickness of a tantalum capping layer and the Hin as-deposited and after annealing;

FIG. 9A shows an Auger depth profile, obtained as-deposited, of a magnetic detection device including a tantalum capping layer having a thickness of 50 Å;

FIG. 9B shows an Auger depth profile, obtained after annealing, of a magnetic detection device including a tantalum capping layer having a thickness of 50 Å;

FIG. 9C shows an Auger depth profile, obtained after annealing, of a magnetic detection device including a tantalum capping layer having a thickness of 70 Å;

FIG. 10A is a transmission electron microscopy (TEM) image, obtained after annealing, of a magnetic detection device including a tantalum capping layer having a thickness of 30 Å;

FIG. 10B is a TEM image, obtained after annealing, of a magnetic detection device including a tantalum capping layer having a thickness of 70 Å; and

FIG. 10C is a TEM image, obtained as-deposited, of a magnetic detection device including a tantalum capping layer having a thickness of 50 Å.

### DESCRIPTION OF THE PREFERRED EMBODIMENTS

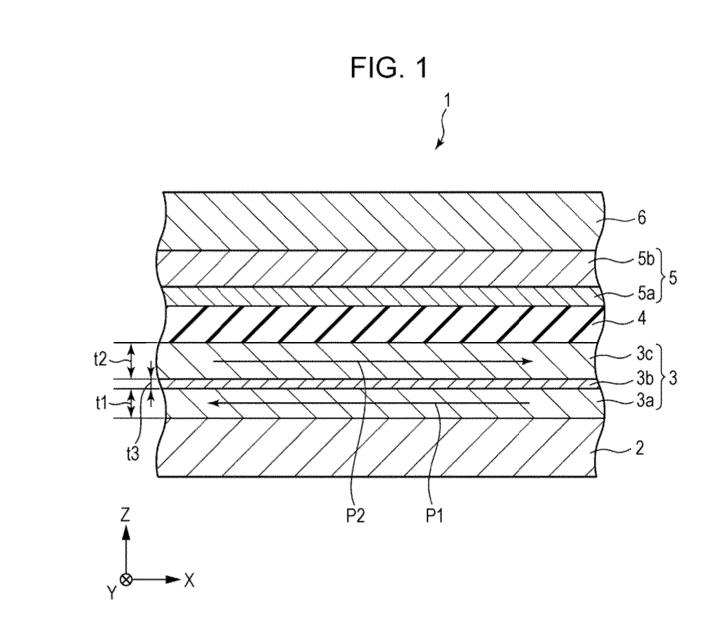

FIG. 1 is a partial enlarged cross-sectional view of a magnetic detection device according to an embodiment of the present invention.

As shown in FIG. 1, a magnetic detection device (giant magnetoresistance (GMR) device) 1 according to this embodiment includes, in order from bottom to top, a seed layer 2, a pinned magnetic layer 3, a nonmagnetic material layer 4, a free magnetic layer 5, and a capping layer 6. The individual layers forming the magnetic detection device 1 are deposited by, for example, sputtering.

The seed layer 2 is formed of, for example, nickel-iron-chromium or chromium. The seed layer 2 has a thickness of about 36 to 60 Å. A base layer of, for example, tantalum, hafnium, niobium, zirconium, titanium, molybdenum, or tungsten may be formed between the seed layer 2 and a substrate (not shown).

The pinned magnetic layer 3 has an artificial antiferromagnetic (AAF) structure including a first magnetic layer 3a, a second magnetic layer 3c, and a nonmagnetic intermediate layer 3b disposed therebetween.

As shown in FIG. 1, the pinned magnetization direction (P1) of the first magnetic layer 3a is antiparallel with the pinned magnetization direction (P2) of the second magnetic layer 3c.

As shown in FIG. 1, the first magnetic layer 3a is formed on the seed layer 2, and the second magnetic layer 3c is formed adjacent to the nonmagnetic material layer 4, described later.

In this embodiment, the first magnetic layer 3a is formed of Fex-Co100-x (where x is preferably 55 to 65 atomic percent), which has a higher coercivity than the material of the second magnetic layer 3c.

As shown in FIG. 1, the first magnetic layer 3a has a smaller thickness than the second magnetic layer 3c, for example, a thickness in the range of 14 to 20.5 Å.

In this embodiment, accordingly, the first magnetic layer 3a has a high, stable coercivity Hc, for example, 50 kA/m or more.

The second magnetic layer 3c adjacent to the nonmagnetic material layer 4 contributes to a magnetoresistance effect (GMR effect). The second magnetic layer 3c is formed of a magnetic material that provides a large difference in mean free path between spin-up conduction electrons and spin-down conduction electrons.

Specifically, the second magnetic layer 3c is formed of Coy-Fe100-y (where y is preferably 85 to less than 100 atomic percent) or cobalt.

The second magnetic layer 3c has a larger thickness than the first magnetic layer 3a, for example, a thickness in the range of 16.5 to 26 Å.

The thicknesses of the first magnetic layer 3a and the second magnetic layer 3c are adjusted so that the difference in magnetization (saturation magnetization Ms·thickness t) between the first magnetic layer 3a and the second magnetic layer 3c is substantially zero.

In this embodiment, the pinned magnetic layer 3 is a self-pinned layer having a synthetic ferri-pinned (SFP) structure. That is, the magnetic detection device 1 includes no antiferromagnetic layer. This avoids the problem of the blocking temperature of an antiferromagnetic layer limiting the temperature characteristics of the magnetic detection device 1.

To more strongly pin the magnetization of the pinned magnetic layer 3, as described above, it is important to increase the coercivity Hc of the first magnetic layer 3a, to adjust the difference in magnetization between the first magnetic layer 3a and the second magnetic layer 3c to substantially zero, and to adjust the thickness of the nonmagnetic intermediate layer 3b so as to increase an antiparallel coupling field resulting from RKKY interaction between the first magnetic layer 3a and the second magnetic layer 3c.

The nonmagnetic intermediate layer 3b disposed between the first magnetic layer 3a and the second magnetic layer 3c is formed of ruthenium. The nonmagnetic intermediate layer 3b preferably has a thickness of 3.4 to 4.2 Å.

The nonmagnetic material layer 4 is formed of a nonmagnetic conductive material such as copper. For tunneling magnetoresistance (TMR) devices, the nonmagnetic material layer 4 may be formed of an insulating material. The free magnetic layer 5 is formed of a soft magnetic material such as nickel-iron, cobalt-iron, or cobalt-iron-nickel. In the example shown in FIG. 1, the free magnetic layer 5 has a layered structure including a cobalt-iron alloy layer 5a and a nickel-iron alloy layer 5b, although it may have any other structure. That is, the free magnetic layer 5 may be formed of any material and may have any structure, such as a single-layer structure, a layered structure, or a synthetic ferri-pinned structure.

The capping layer 6, which is the top layer of the layered film, is formed of tantalum; it is hereinafter referred to as “tantalum capping layer 6.” The as-deposited thickness t1 of the tantalum capping layer 6 is 55 Å or more. The thickness t1 refers to the as-deposited thickness unless otherwise specified.

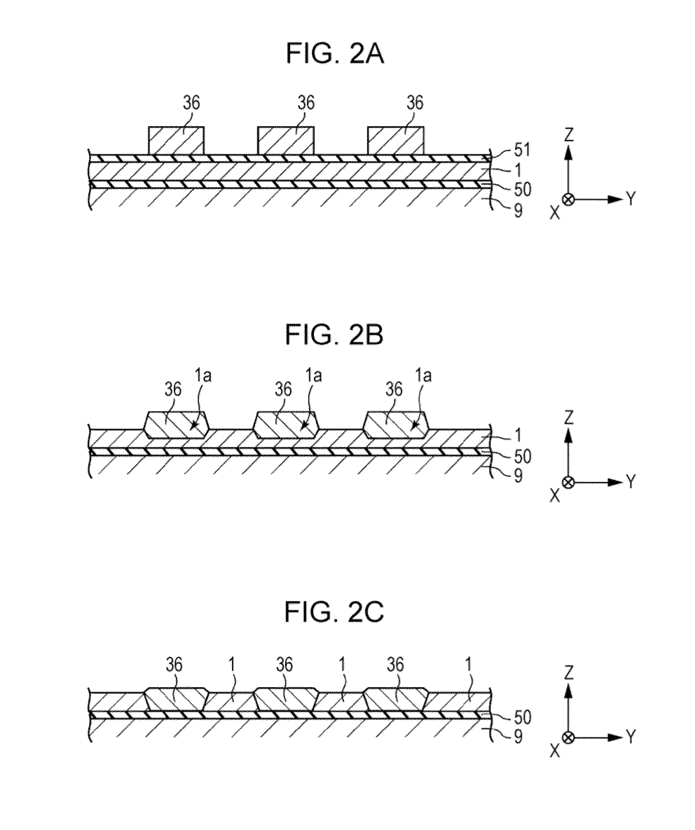

FIGS. 2A to 2C are partial longitudinal sectional views showing the positional relationship between the magnetic detection device 1 shown in FIG. 1 and hard bias layers connected to the magnetic detection device 1.

As shown in FIG. 2A, the magnetic detection device 1 is formed on a support substrate 9 with an insulating layer 50 therebetween. As shown in FIG. 2A, an insulating layer 51 is formed on the magnetic detection device 1, and hard bias layers 36 are formed on a flat surface of the insulating layer 51.

Alternatively, as shown in FIG. 2B, the magnetic detection device 1 may be partially removed to form recesses 1a, and the hard bias layers 36 may be formed in the recesses 1a. Alternatively, as shown in FIG. 2C, the magnetic detection device 1 may be completely removed from the positions where the hard bias layers 36 are to be formed, and the hard bias layers 36 may be formed between the divided magnetic detection devices 1.

Thus, a biasing field is applied to the free magnetic layer 5 (see FIG. 1) forming the magnetic detection device 1 in the Y direction to magnetize the free magnetic layer 5 in a direction perpendicular to the pinned magnetization direction of the pinned magnetic layer 3.

In this embodiment, a plurality of magnetic detection devices 1 elongated in the Y direction, as shown in FIGS. 2A to 2C, are arranged at intervals in the X direction, and the ends of the magnetic detection devices 1 are connected to each other via a conductive layer so as to form a meander pattern.

In this embodiment, the nonmagnetic material layer 4 forming the magnetic detection device 1 is a nonmagnetic conductive layer, such as a copper layer, through which a current flows in a direction substantially parallel to the surface of the layered film.

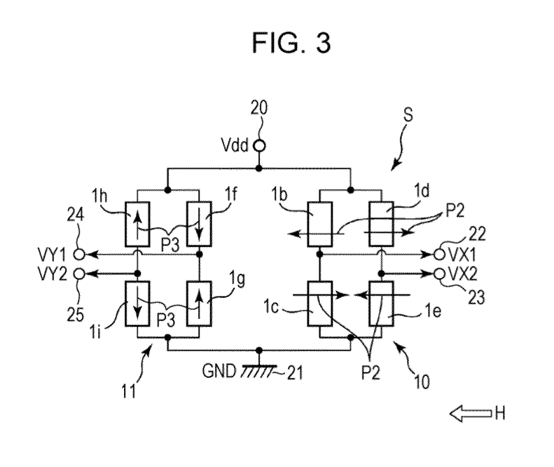

A plurality of magnetic detection devices 1 formed in a meander pattern form bridge circuits shown in FIG. 3. In FIG. 3, the individual magnetic detection devices 1 are distinguished by referring to them with different reference signs, namely, as “first magnetic detection devices 1b to 1e” and “second magnetic detection devices 1f to 1i.”

As shown in FIG. 3, a magnetic sensor S according to this embodiment includes a first bridge circuit 10 including four first magnetic detection devices 1b to 1e and a second bridge circuit 11 including four second magnetic detection devices 1f to 1i.

As shown in FIG. 3, the sensitive axis direction of the first magnetic detection devices 1b and 1e forming the first bridge circuit 10 (the pinned magnetization direction (P2) of the second magnetic layer 3c forming the pinned magnetic layer 3 shown in FIG. 1) is antiparallel with the sensitive axis direction of the first magnetic detection devices 1c and 1d. The first magnetic detection device 1b is series-connected to the first magnetic detection device 1c, and the first magnetic detection device 1d is series-connected to the first magnetic detection device 1e. The first magnetic detection devices 1b and 1d are connected to an input terminal (Vdd) 20, and the first magnetic detection devices 1c and 1e are connected to a ground terminal (GND) 21. An output terminal (VX1) 22 is connected between the first magnetic detection devices 1b and 1c, and an output terminal (VX2) 23 is connected between the first magnetic detection devices 1d and 1e.

As shown in FIG. 3, the sensitive axis direction of the second magnetic detection devices 1f and 1i forming the second bridge circuit 11 (denoted as “P3” in FIG. 3) is antiparallel with the sensitive axis direction of the second magnetic detection devices 1g and 1h. The second magnetic detection device 1f is series-connected to the second magnetic detection device 1g, and the second magnetic detection device 1h is series-connected to the second magnetic detection device 1i. The second magnetic detection devices 1f and 1h are connected to the input terminal (Vdd) 20, and the second magnetic detection devices 1g and 1i are connected to the ground terminal (GND) 21. An output terminal (VY1) 24 is connected between the second magnetic detection devices 1f and 1g, and an output terminal (VY2) 25 is connected between the second magnetic detection devices 1h and 1i.

As shown in FIG. 3, the sensitive axis direction (P2) of the first magnetic detection devices 1b to 1e is perpendicular to the sensitive axis direction (P3) of the second magnetic detection devices 1f to 1i.

For example, a magnet (not shown) is disposed opposite the magnetic sensor S shown in FIG. 3 at a distance in the height direction (Z). This magnet applies an external magnetic field H to the magnetic detection devices 1b to 1i.

For example, if the external magnetic field H is applied in the direction indicated in FIG. 3, the electrical resistance of the first magnetic detection device 1b and 1e forming the first bridge circuit 10 decreases because the sensitive axis direction thereof agrees with the direction of the external magnetic field H. Conversely, the electrical resistance of the first magnetic detection device 1c and 1d increases because the sensitive axis direction thereof is opposite to the direction of the external magnetic field H. Accordingly, the midpoint potentials at the output terminals 22 and 23 vary, thus producing a sensor output. In the second bridge circuit 11, the second magnetic detection devices 1f to 1i have equal electrical resistance because the external magnetic field H is applied perpendicularly to the sensitive axis direction (P3). Accordingly, the midpoint potentials at the output terminals 24 and 25 do not vary (the sensor output is zero). The sensor outputs of the bridge circuits 10 and 11 vary with the direction of the external magnetic field H.

Based on the sensor outputs produced by the bridge circuits 10 and 11, the movement direction and distance (relative position) of the magnet can be determined

The magnetic sensor S according to this embodiment may include, for example, a bridge circuit including a single magnetic detection device on a substrate, with the remaining resistors being fixed resistors.

Examples of applications of the magnetic sensor S according to this embodiment include, but not limited to, geomagnetic sensors, rotary sensors, and magnetic switches.

The magnetic detection device 1 according to this embodiment is characterized in that the as-deposited thickness t1 of the tantalum capping layer 6 is adjusted in the range of 55 Å or more.

The magnetic detection device 1 according to this embodiment, which includes the self-pinned magnetic layer 3 without an antiferromagnetic layer in the layered film, requires no field annealing. The magnetic detection device 1, however, has to be annealed without a magnetic field (hereinafter referred to as “field-free annealing”) in air or an inert gas flow such as nitrogen so that the properties thereof do not vary after a high-temperature process following the deposition of the magnetic detection device 1 in the process of manufacturing the magnetic sensor S or after the use of the magnetic sensor S at high temperatures. The annealing apparatus used therefor is usually inexpensive and requires a short period of time for annealing. An experiment conducted this time, however, has revealed that a tantalum capping layer 6 having a small thickness t1 has a problem in inhibiting property degradation due to oxidation of the tantalum capping layer 6 and the underlying layers.

In this embodiment, therefore, the as-deposited thickness t1 of the tantalum capping layer 6 in the magnetic detection device 1 including the self-pinned magnetic layer 3 is set to 55 Å or more based on the experimental results described later. The lower limit of the thickness t1 of the tantalum capping layer 6 is set to 55 Å because a thickness t1 of less than 55 Å results in a sharply increased interlayer coupling field Hin between the free magnetic layer 5 and the pinned magnetic layer 3 and therefore a sharply decreased ΔMR (rate of change in resistance). If the tantalum capping layer 6 has a thickness t1 of 55 Å or more, only the surface side thereof is oxidized after field-free annealing, with some metallic tantalum remaining, and no or little oxygen reaches the free magnetic layer 5 located directly under the tantalum capping layer 6. This presumably maintains the interior of the free magnetic layer 5 and the interface between the free magnetic layer 5 and the nonmagnetic material layer 4 in substantially the same condition as the as-deposited condition, thus stably providing superior soft magnetic properties. The upper limit of the thickness of the tantalum capping layer 6 is not specified. As the thickness of the tantalum capping layer 6 is extremely increased, however, more current is shunted into the tantalum capping layer 6 (shunt loss), thus decreasing ΔMR. The thickness of the tantalum capping layer 6 can be increased so that more current is shunted into the tantalum capping layer 6, thereby finely adjusting ΔMR. By adjusting the thickness of the tantalum capping layer 6, ΔMR can be adjusted without degrading the reliability of other magnetic properties.

In this embodiment, the thickness of the tantalum capping layer 6 is preferably limited to 100 Å. The experiments described later have demonstrated that a tantalum capping layer 6 having a thickness t1 of 100 Å or less limits a decrease in ΔMR after field-free annealing to about 0.5% as compared with the as-deposited ΔMR of a magnetic detection device including a tantalum capping layer 6 having a thickness of 30 Å.

According to this embodiment, as described above, the magnetic detection device 1 including the self-pinned magnetic layer 3 stably provides superior soft magnetic properties. In this embodiment, Hin can be reduced to 20 Oe or less, preferably to substantially zero, and ΔMR is higher than or equal to that before annealing.

The magnetic sensor S shown in FIG. 3, including the self-pinned magnetic detection devices 1 according to this embodiment, stably provides superior soft magnetic properties and can be used for various applications with its superior output characteristics.

The thickness t1 of the tantalum capping layer 6, which is set to 55 Å or more in this embodiment, is the as-deposited thickness. After post-deposition field-free annealing, the thickness of the tantalum capping layer 6 becomes larger than the as-deposited thickness as a result of partial oxidation. The as-deposited thickness t1 of the tantalum capping layer 6 can be estimated from the annealed condition, as shown in the experimental results described later. If the tantalum capping layer 6 has a thickness t1 of 55 Å, the metallic tantalum remaining after field-free annealing has a thickness of about 5 Å, and the tantalum oxide has a thickness of about 100 Å. If the tantalum capping layer 6 has a thickness t1 of 70 Å, the remaining metallic tantalum has a thickness of about 20 Å, and the tantalum oxide has a thickness of about 100 Å. Although the thickness after field-free annealing varies with annealing temperature and annealing time, the thickness is generally within the above range if the annealing temperature is about 250° C. to 300° C. and the annealing time is about one to four hours. The thicknesses of the tantalum oxide and the metallic tantalum can be determined using, for example, a TEM image, as described later. The as-deposited thickness t1 of the tantalum capping layer 6 can be estimated from the thicknesses of the tantalum oxide and the metallic tantalum and the thickness ratio thereof.

In this embodiment, the thickness t1 of the tantalum capping layer 6 is preferably adjusted within the range of 70 to 100 Å. By shifting the lower limit of the thickness t1 of the tantalum capping layer 6 from 55 Å to 70 Å, superior soft magnetic properties can be stably provided even if the as-deposited thickness t1 deviates slightly from the target thickness.

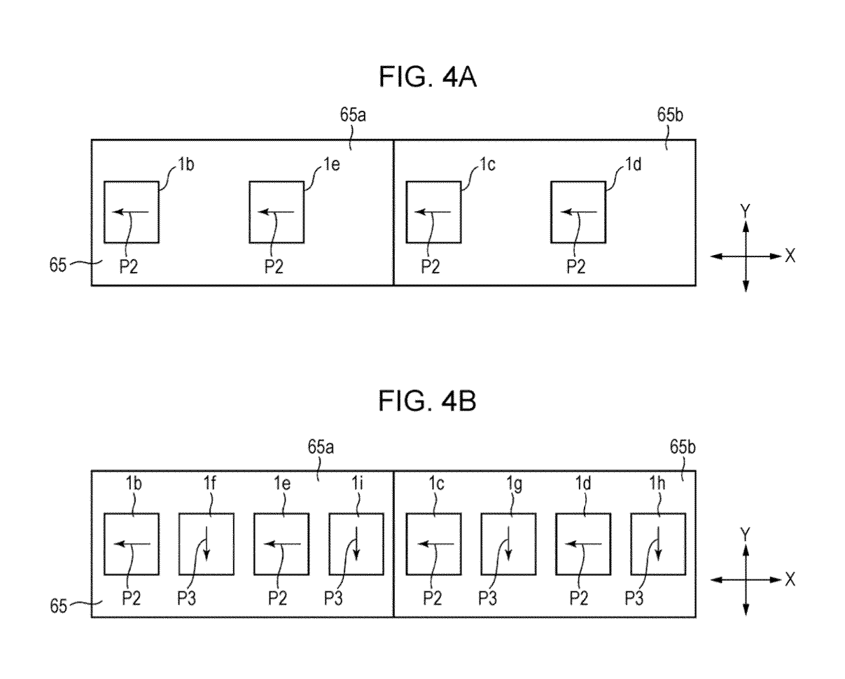

The magnetic sensor S shown in FIG. 3 can be manufactured, for example, as follows. FIGS. 4A and 4B are plan views, each illustrating a step of a method for manufacturing the magnetic sensor S according to this embodiment.

Referring to FIG. 4A, a substrate 65 is prepared. The substrate 65 has a first sensor region 65a and a second sensor region 65b.

In the step shown in FIG. 4A, two first magnetic detection devices 1b and 1e are formed on the first sensor region 65a of the substrate 65, and two first magnetic detection devices 1c and 1d are formed on the second sensor region 65b of the substrate 65. The self-pinned magnetic layer 3 having an AAF structure (see FIG. 1) is deposited in a magnetic field such that the magnetization thereof is pinned in the X direction. The direction P2 shown in FIG. 4A is the pinned magnetization direction (sensitive axis direction) of the second magnetic layer 3c of the pinned magnetic layer 3 forming the first magnetic detection devices 1b to 1e.

In the next step shown in FIG. 4B, two second magnetic detection devices 1f and 1i are formed on the first sensor region 65a of the substrate 65, and two second magnetic detection devices 1g and 1h are formed on the second sensor region 65b of the substrate 65. The self-pinned magnetic layer 3 having an AAF structure (see FIG. 1) is deposited in a magnetic field such that the magnetization thereof is pinned in the Y direction. The direction P3 shown in FIG. 4B is the pinned magnetization direction (sensitive axis direction) of the second magnetic layer 3c of the pinned magnetic layer 3 forming the second magnetic detection devices 1f to 1i.

In this embodiment, the pinned magnetic layer 3 is not annealed for magnetization pinning control. In the step shown in FIG. 4B, therefore, a magnetic field can be applied to pin the magnetization of the pinned magnetic layer 3 of the second magnetic detection devices 1f to 1i in the Y direction while appropriately maintaining, in the X direction, the pinned magnetization direction (P2) of the pinned magnetic layer 3 of the first magnetic detection devices 1b to 1e formed in the step shown in FIG. 4A.

In this embodiment, the tantalum capping layer 6 of the magnetic detection devices 1b to 1i is deposited to a thickness of 55 Å or more, preferably 55 to 100 Å, more preferably 70 to 100 Å.

Subsequently, hard bias layers 36 are formed on both sides of the magnetic detection devices 1b to 1i such that the combined planar pattern of the magnetic detection devices 1b to 1i and the hard bias layers 36 is a meander pattern.

In this embodiment, after the deposition of the magnetic detection devices 1b to 1i, they are subjected to field-free annealing in air or an inert gas flow (such as nitrogen, which is inexpensive). Field-free annealing may be performed anytime after the deposition of the magnetic detection devices 1b to 1i. Field-free annealing is performed before a high-temperature process involved in the process of manufacturing the magnetic sensor S or, if no high-temperature process is performed, during the process of manufacturing the magnetic sensor S.

The annealing temperature is about 250° C. to 300° C., and the annealing time is about one to four hours.

Subsequently, the first sensor region 65a and the second sensor region 65b shown in FIGS. 4A and 4B are separated from each other. With the second sensor region 65b inverted 180° with respect to the first sensor region 65a, the input terminal 20, the ground terminal 21, and the output terminals 22 to 25 shown in FIG. 3 are electrically connected to the first sensor region 65a and the second sensor region 65b. In this way, the first bridge circuit 10 and the second bridge circuit 11 shown in FIG. 3 can be formed.

### EXAMPLES

### R—H Curve Experiment for Varying Thicknesses of Tantalum Capping Layer

Magnetic detection devices having the following layered films were fabricated:

Substrate/seed layer: Ni—Fe—Cr (42)/pinned magnetic layer [first magnetic layer: _{Fe}_{60 at %}—Co_{40 at %} (18.7)/nonmagnetic intermediate layer: Ru (3.6)/second magnetic layer: Co_{50 at %}—Fe_{10 at %} (24)]/nonmagnetic material layer: Cu (22)/free magnetic layer [Co_{90 at %}—Fe_{10 at %} (12)/Ni—Fe (20)]/capping layer: Ta (X)

The values in parentheses indicate the thicknesses of the individual layers in angstroms.

The as-deposited R—H curve was measured first.

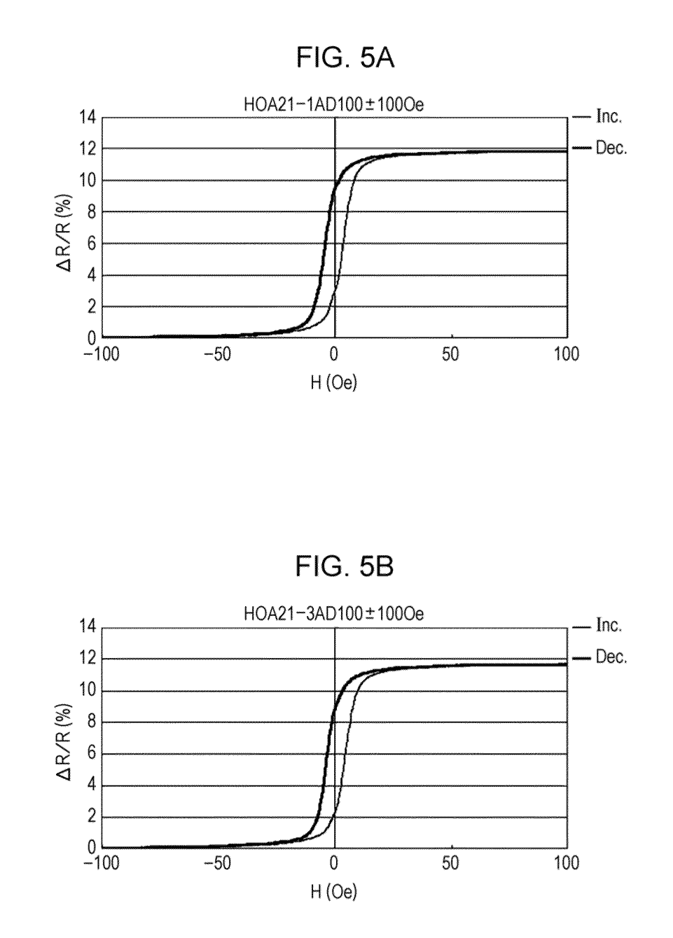

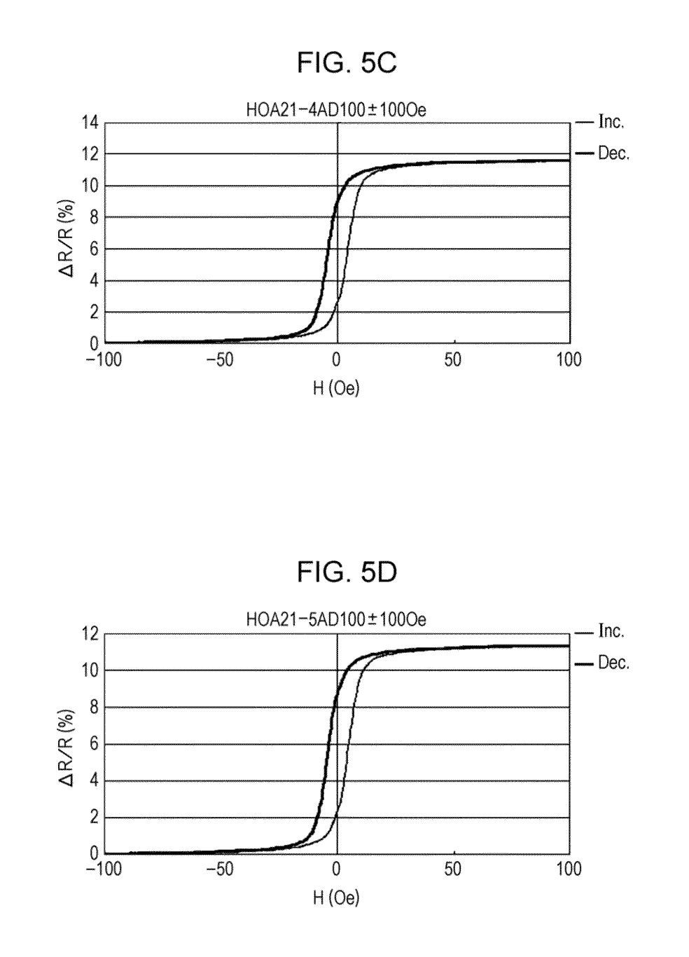

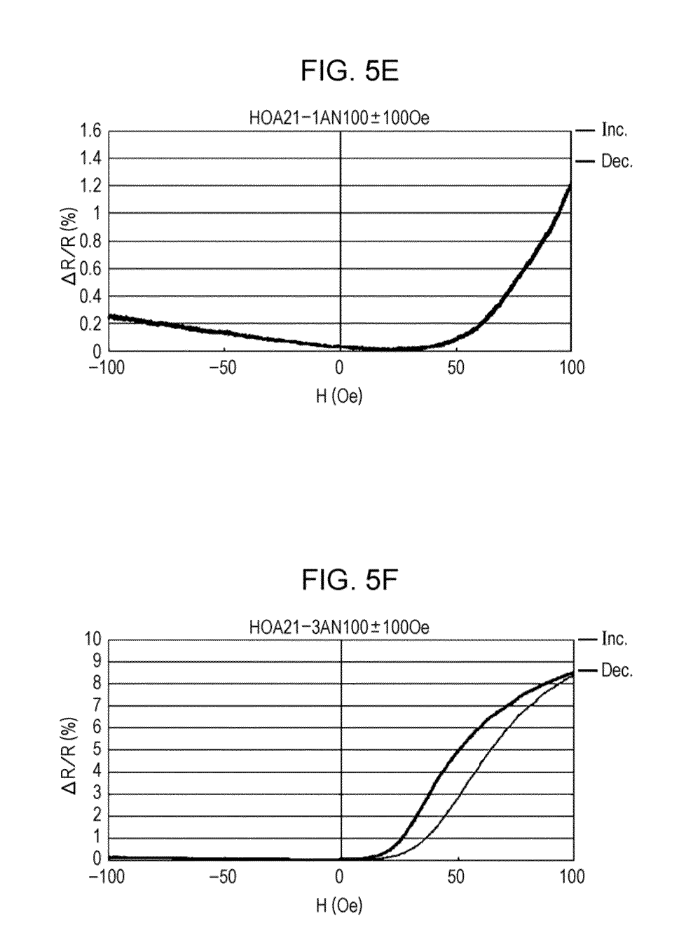

In the experiment, the R—H curves of magnetic detection devices including tantalum capping layers having thicknesses of 30, 50, 55, and 70 Å were measured. FIG. 5A shows the R—H curve (as-deposited) of the magnetic detection device including a tantalum capping layer having a thickness of 30 Å. FIG. 5B shows the R—H curve (as-deposited) of the magnetic detection device including a tantalum capping layer having a thickness of 50 Å. FIG. 5C shows the R—H curve (as-deposited) of the magnetic detection device including a tantalum capping layer having a thickness of 55 Å. FIG. 5D shows the R—H curve (as-deposited) of the magnetic detection device including a tantalum capping layer having a thickness of 70 Å. In the experiment, the external magnetic field applied to the magnetic detection devices was in the range of ±100 Oe. A positive external magnetic field is opposite in direction to the pinned magnetization direction of the pinned magnetic layer, and a negative external magnetic field is equal in direction to the pinned magnetization direction of the pinned magnetic layer.

In FIGS. 5A to 5D, the interlayer coupling field Hin between the free magnetic layer and the pinned magnetic layer is determined by the magnetic field intensity from the “midpoint” of the hysteresis loop to a line at an external magnetic field H of 0 (Oe), where the midpoint is the middle value between the maximum ΔMR and minimum ΔMR of the R—H curve and is the value in the center of the width of the hysteresis loop. FIG. 5A shows a midpoint O. As shown in FIG. 5A, the midpoint O lies substantially on the line at an external magnetic field H of 0 (Oe). Hence, Hin is substantially 0 (Oe).

FIGS. 5A to 5D demonstrate that the as-deposited Hin is substantially 0 (Oe) irrespective of the thickness of the tantalum capping layer.

Next, the magnetic detection devices were subjected to field-free annealing in a nitrogen gas flow at 270° C. for three hours. The R—H curves of the magnetic detection devices were then measured. FIG. 5E shows the R—H curve (after field-free annealing) of the magnetic detection device including a tantalum capping layer having a thickness of 30 Å. FIG. 5F shows the R—H curve (after field-free annealing) of the magnetic detection device including a tantalum capping layer having a thickness of 50 Å. FIG. 5G shows the R—H curve (after field-free annealing) of the magnetic detection device including a tantalum capping layer having a thickness of 55 Å. FIG. 5H shows the R—H curve (after field-free annealing) of the magnetic detection device including a tantalum capping layer having a thickness of 70 Å. In the experiment, the external magnetic field was in the range of ±100 Oe.

As shown in FIGS. 5G and 5H, the magnetic detection devices including tantalum capping layers having thicknesses of 55 and 70 Å had slightly higher coercivities Hc after field-free annealing than as-deposited (the width of the hysteresis loop along the horizontal axis through the midpoint is equivalent to twice the coercivity), although they had little variation in ΔMR or Hin. Rather, as described later, ΔMR was slightly higher after field-free annealing than as-deposited.

In contrast, as shown in FIG. 5E, the ΔMR of the magnetic detection device including a tantalum capping layer having a thickness of 30 Å varied in the range of ±100 Oe without reaching saturation. FIG. 5I shows the same R—H curve over an extended range, namely, ±500 Oe, so that the entire hysteresis loop can be seen. As shown in FIG. 5I, the midpoint 0 of the hysteresis loop deviated largely from the line at an external magnetic field H of 0 (Oe), meaning that Hin increased largely. Specifically, Hin increased to about 90 Oe. In addition, the ΔMR at an external magnetic field H of 100 Oe (see FIG. 5E) decreased largely from the as-deposited ΔMR in FIG. 5A.

FIG. 5F shows the R—H curve (range of external magnetic field: ±100 Oe) of the magnetic detection device including a tantalum capping layer having a thickness of 50 Å. FIG. 5J shows the R—H curve (range of external magnetic field: ±500 Oe) of the magnetic detection device including a tantalum capping layer having a thickness of 50 Å. As shown in FIGS. 5F and 5J, the midpoint O of the hysteresis loop deviated from the line at an external magnetic field H of 0 (Oe), and Hin increased to about 50 Oe. In addition, the ΔMR at an external magnetic field H of 100 Oe (see FIG. 5F) obviously decreased from the as-deposited ΔMR in FIG. 5B.

These experimental results demonstrate that a major factor in a decrease in ΔMR is an increase in Hin. One possible cause of the increase in Hin is damage due to oxygen reaching the interior of the free magnetic layer and the interface between the free magnetic layer and the nonmagnetic material layer, as shown by the experimental results described later.

Relationship between Thickness of Tantalum Capping Layer and ΔMR and Relationship between Thickness of Tantalum Capping Layer and Hin

Based on the above experimental results of the R—H curves, the relationship between the thickness of the tantalum capping layer and ΔMR and the relationship between the thickness of the tantalum capping layer and Hin were examined.

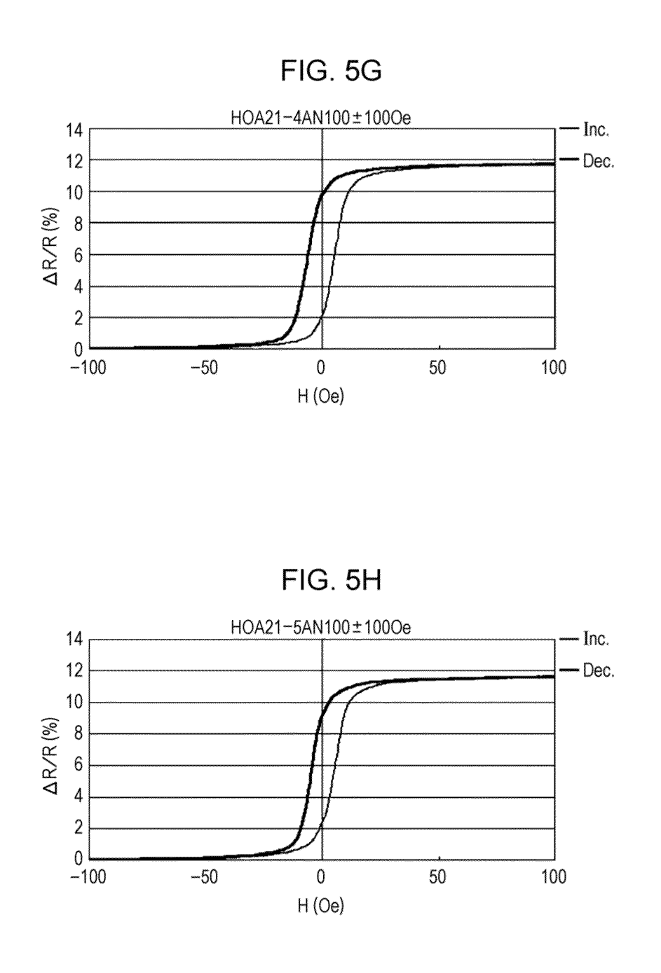

FIG. 6 is a graph showing the relationship between the thickness of the tantalum capping layer and ΔMR. FIG. 6 shows both the as-deposited ΔMR and the ΔMR after field-free annealing (annealing in a nitrogen gas flow at 270° C. for three hours). The measurements of ΔMR were those obtained with an external magnetic field of 100 Oe.

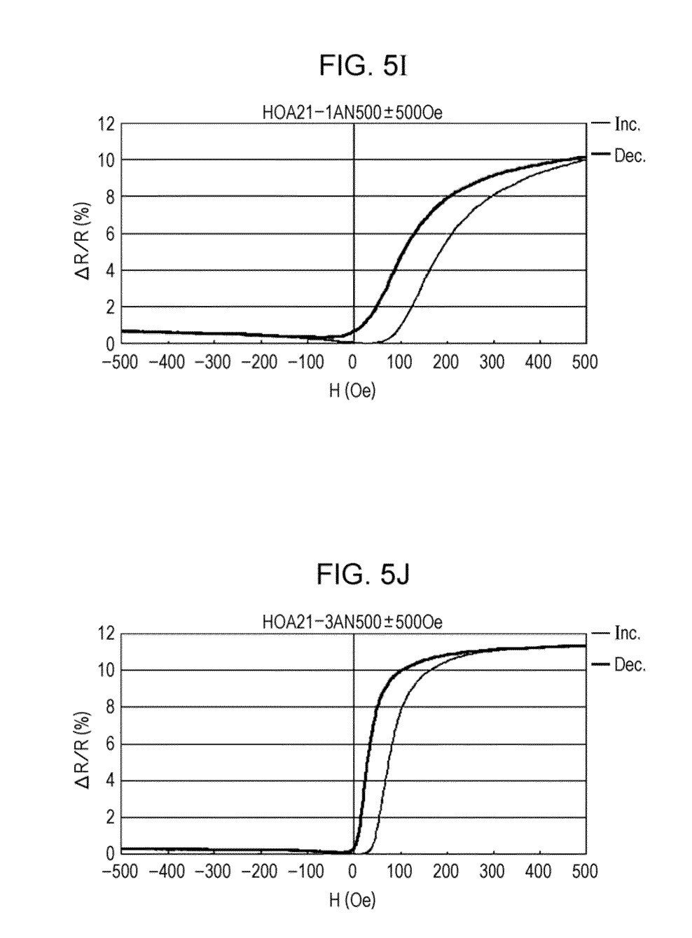

FIG. 7 is a graph showing the relationship between the thickness of the tantalum capping layer and ΔMR, having the same horizontal axis as in FIG. 6 and an extended vertical axis.

FIGS. 6 and 7 demonstrate that a high, stable ΔMR can be maintained after field-free annealing if the tantalum capping layer has a thickness of 55 Å or more. FIGS. 6 and 7 also demonstrate that a higher ΔMR can be achieved after field-free annealing than as-deposited if the tantalum capping layer has a thickness of 55 Å or more.

FIGS. 6 and 7 demonstrate that the ΔMR after field-free annealing is maximized if the thickness of the tantalum capping layer is 55 Å and decreases gradually as the thickness of the tantalum capping layer is increased above 55 Å. This is because more current is shunted into a thicker tantalum capping layer (shunt loss). Based on this effect, the thickness of the tantalum capping layer can be adjusted to finely adjust ΔMR and therefore the sensor output of a bridge circuit.

It turned out that the thickness of the tantalum capping layer is preferably set to 100 Å or less in order to limit a decrease in ΔMR after field-free annealing to 0.5% as compared with the as-deposited ΔMR (=11.9%) of the magnetic detection device including a tantalum capping layer having a thickness of 30 Å.

In addition, if the tantalum capping layer has a thickness of 70 Å or more, a high, stable ΔMR can be achieved even if the as-deposited thickness of the tantalum capping layer deviates slightly from the target thickness.

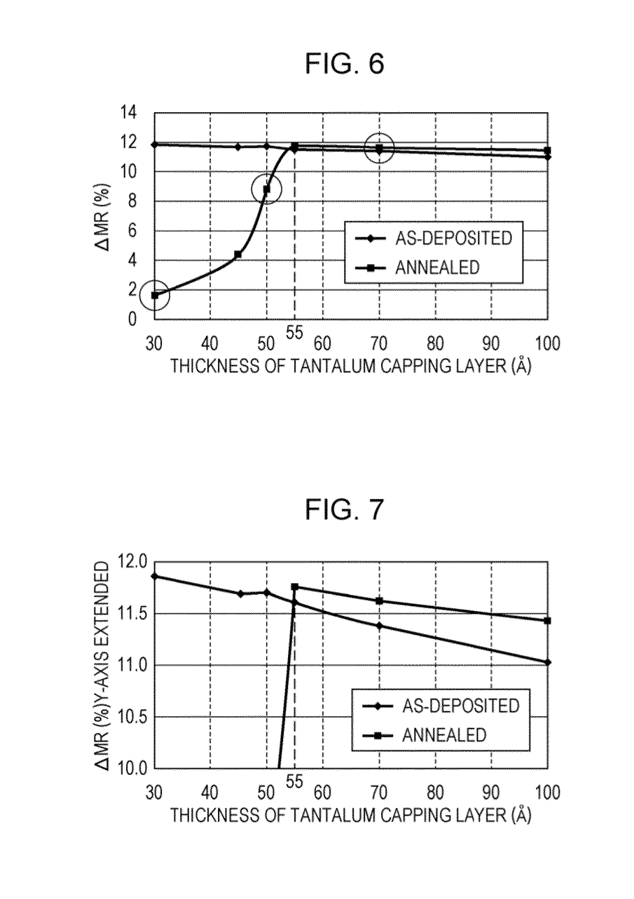

FIG. 8 is a graph showing the relationship between the thickness of the tantalum capping layer and Hin. FIG. 8 shows both the as-deposited Hin and the Hin after field-free annealing (annealing in a nitrogen gas flow at 270° C. for three hours).

FIG. 8 demonstrates that a tantalum capping layer having a thickness of 55 Å or more reduces the Hin after field-free annealing to substantially 0 Oe. As shown in FIG. 8, the as-deposited Hin can be reduced to substantially zero irrespective of the thickness of the tantalum capping layer. The Hin after field-free annealing increases as the thickness of the tantalum capping layer is decreased. In particular, the Hin after field-free annealing rises sharply at a thickness of 55 Å, as illustrated with the R—H curves in FIGS. 5A to 5J.

Based on the above experimental results, the thickness of the tantalum capping layer is set to 55 Å or more, preferably 55 to 100 Å, more preferably 70 to 100 Å.

### Results of Auger Depth Profile Analysis

Next, the relationship between the thickness of the tantalum capping layer and the state of oxidation in the layered film was analyzed by Auger depth profile analysis. The structure of the layered film and the field-free annealing conditions were identical to those of the above experiment.

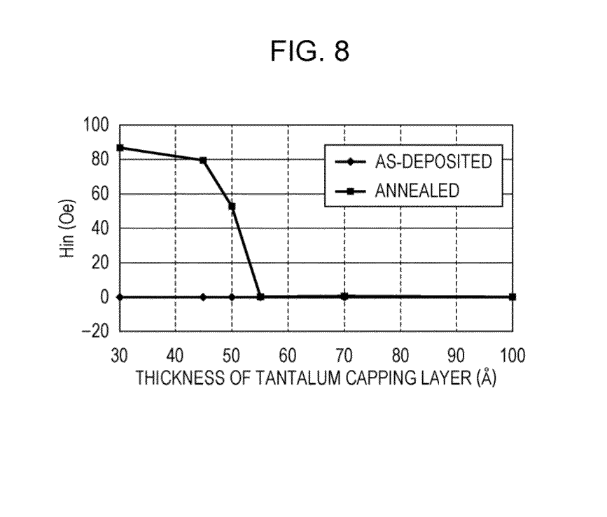

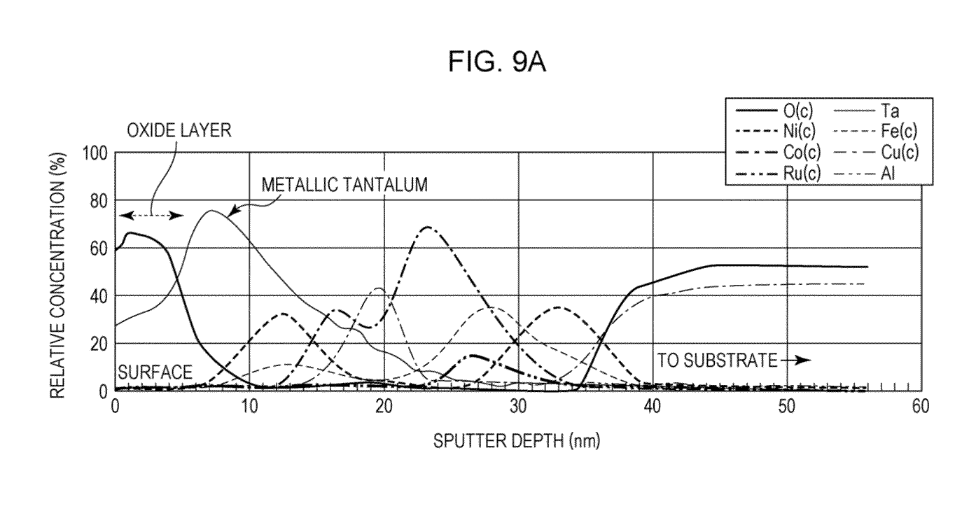

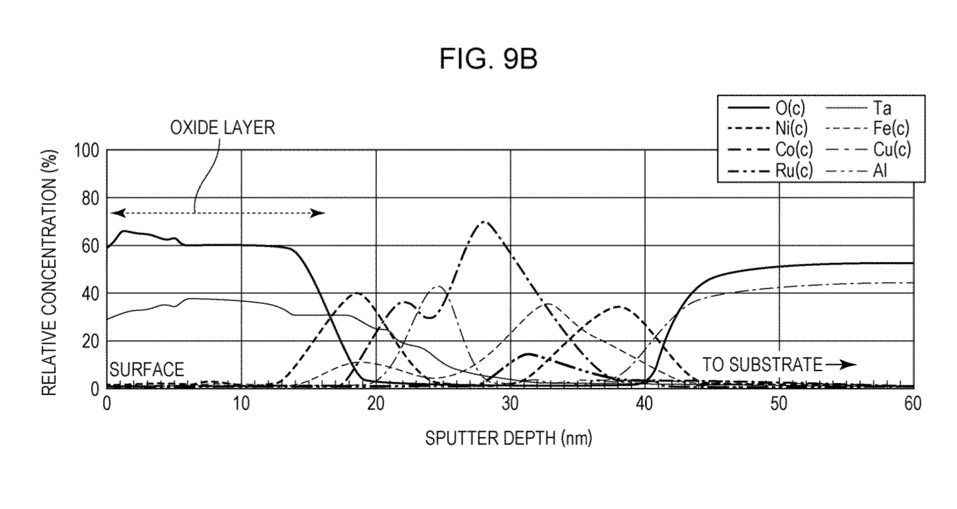

FIG. 9A shows an Auger depth profile, obtained as-deposited, of the magnetic detection device including a tantalum capping layer having a thickness of 50 Å. FIG. 9B shows an Auger depth profile, obtained after field-free annealing, of the magnetic detection device including a tantalum capping layer having a thickness of 50 Å. FIG. 9C shows an Auger depth profile, obtained after field-free annealing, of the magnetic detection device including a tantalum capping layer having a thickness of 70 Å.

In FIG. 9A, which shows the experimental results obtained as-deposited, oxidation ceased halfway from the surface of the tantalum capping layer (thickness: 50 Å), and no oxygen reached the free magnetic layer (nickel-iron).

In FIG. 9B, which shows the results for the tantalum capping layer having a thickness of 50 A and subjected to field-free annealing, substantially the entire tantalum capping layer was oxidized, and oxygen reached the free magnetic layer. This demonstrates that a tantalum capping layer having a thickness of 50 Å cannot protect the free magnetic layer from oxidation.

In contrast, in FIG. 9C, which shows the results for the tantalum capping layer having a thickness of 70 A and subjected to field-free annealing, some metallic tantalum remained in the tantalum capping layer (the portion indicated by the arrow in FIG. 9C), and no or little oxygen reached the free magnetic layer.

### Results of TEM Image Analysis

Next, the condition of the tantalum capping layer was analyzed using TEM images. The structure of the layered film and the field-free annealing conditions were identical to those of the above experiment.

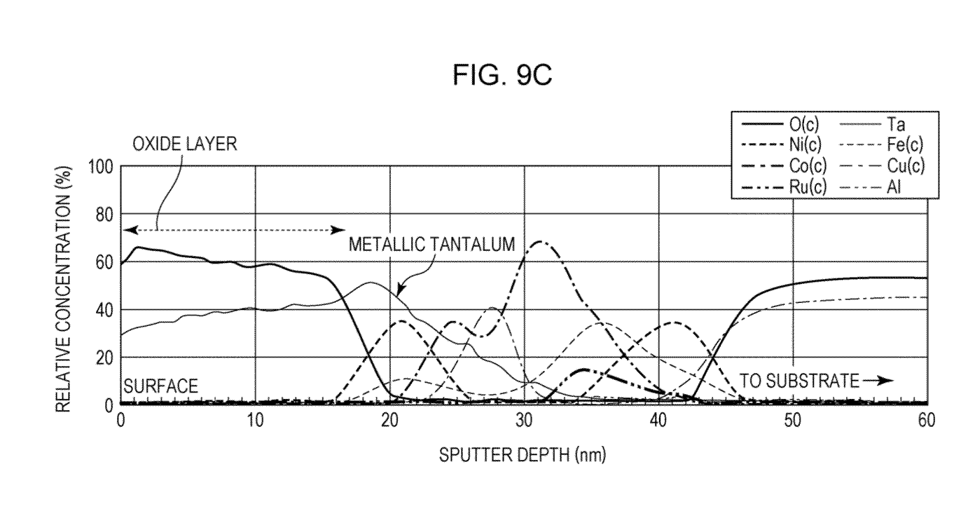

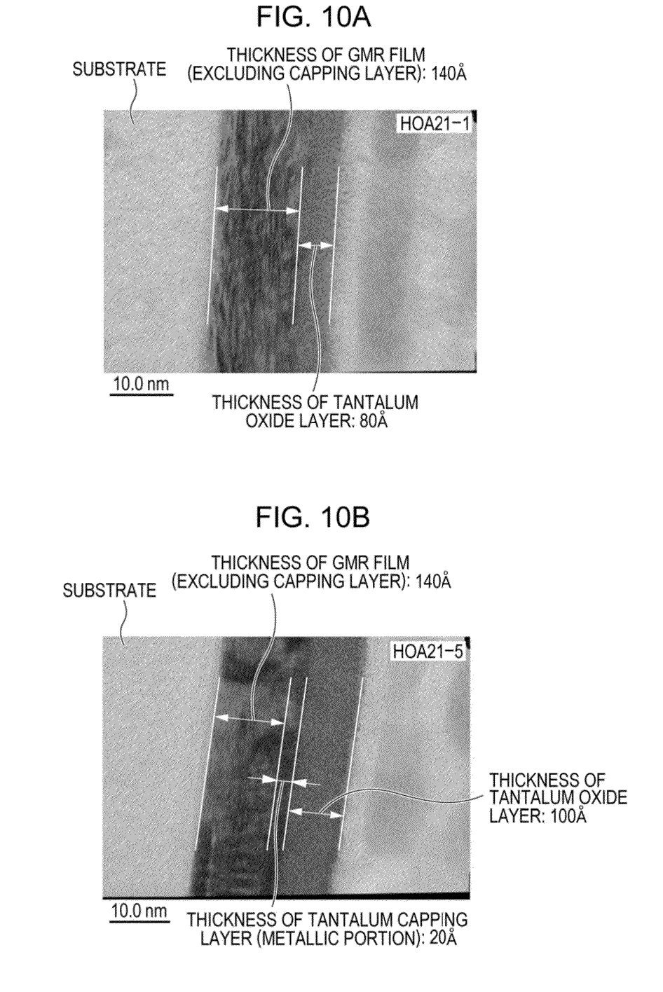

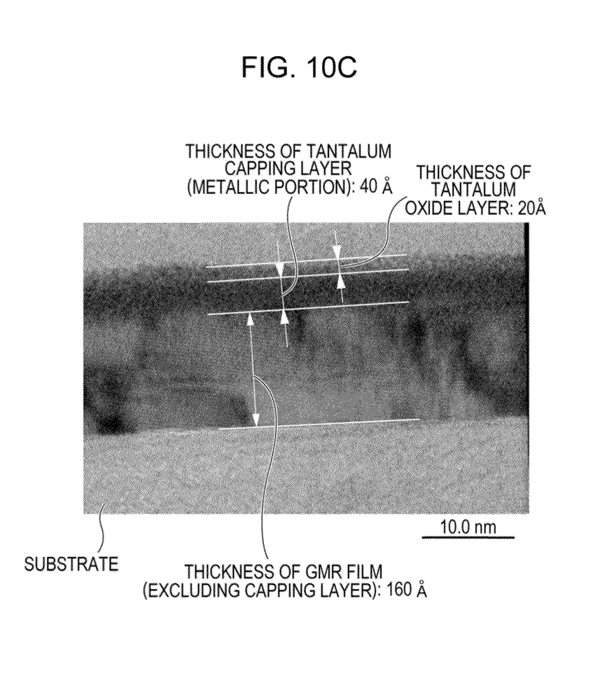

FIG. 10A is a TEM image, obtained after field-free annealing, of the magnetic detection device including a tantalum capping layer having a thickness of 30 Å. FIG. 10B is a TEM image, obtained after field-free annealing, of the magnetic detection device including a tantalum capping layer having a thickness of 70 Å.

In FIG. 10A, the entire tantalum capping layer was oxidized, with no metallic tantalum remaining This suggests that the tantalum capping layer lost its oxidation-preventing function and failed to inhibit oxidative damage to the underlying layers. In FIG. 10A, the thickness of the tantalum capping layer increased from 30 Å (as-deposited thickness) to about 80 Å after field-free annealing.

In contrast, in FIG. 10B, a metallic tantalum layer having a thickness of about 20 A remained Accordingly, the tantalum capping layer was oxidized to a depth of 50 Å, and the oxidized portion expanded to a thickness of about 100 Å. This demonstrates that the tantalum capping layer maintained its oxidation-preventing function and inhibited oxidative damage to the underlying layers.

FIG. 10C is a TEM image, obtained as-deposited, of the magnetic detection device including a tantalum capping layer having a thickness of 50 Å. In the experiment, the first magnetic layer (iron-cobalt) forming the pinned magnetic layer had a thickness of 16.5 Å, the nonmagnetic intermediate layer (ruthenium) had a thickness of 4 Å, the second magnetic layer (cobalt-iron) had a thickness of 20 Å, the cobalt-iron layer forming the free magnetic layer had a thickness of 10 Å, and the nickel-iron layer forming the free magnetic layer had a thickness of 40 Å. The other layers had the same thicknesses as those of the experiments described above.

FIG. 10C demonstrates that a tantalum capping layer is partially oxidized when the magnetic detection device is exposed to air, even without field-free annealing. As shown in FIG. 10C, the tantalum capping layer was oxidized to a depth of about 10 Å, and the oxidized portion expanded to a thickness of about 20 Å.

The experimental results shown in FIGS. 9A to 9C and 10A to 10C suggest that the magnetic detection device of the example according to the present invention had some metallic tantalum remaining after field-free annealing, thus inhibiting oxidative damage to the underlying layers. This demonstrates that the magnetic detection device stably provides superior performance.

By examining the condition of the interior of the tantalum capping layer using, for example, a TEM image such as those in FIGS. 10A to 10C, the thickness ratio of the remaining metallic tantalum layer to the tantalum oxide layer and the thicknesses of the metallic tantalum layer and the tantalum oxide layer can be measured to estimate the as-deposited thickness of the tantalum capping layer.

1. A magnetic detection device having a layered film comprising:
a self-pinned magnetic layer including:
a first magnetic layer having a first magnetization;
a second magnetic layer having a second magnetization pinned in antiparallel with the first magnetization; and
a nonmagnetic intermediate layer disposed between the first magnetic layer and the second magnetic layer;
a free magnetic layer;
a nonmagnetic material layer disposed between the self-pinned magnetic layer and the free magnetic layer; and
a top capping layer containing tantalum, formed on the free magnetic layer, an as-deposited thickness of the capping layer being 55 Å or more.

2. The magnetic detection device according to claim 1, wherein the as-deposited thickness of the capping layer is 100 Å or less.

3. The magnetic detection device according to claim 1, wherein the capping layer includes a portion formed of metallic tantalum adjacent to the free magnetic layer.

4. The magnetic detection device according to claim 1, wherein the as-deposited thickness of the capping layer is 70 to 100 Å.

5. A magnetic sensor comprising:
a substrate; and
a plurality of magnetic detection devices each according to claim 1 arranged on the substrate, the plurality of magnetic detection devices having different sensitive axis directions.

6. A method for manufacturing a magnetic detection device having a layered film including a pinned magnetic layer, a free magnetic layer, and a nonmagnetic material layer disposed therebetween, the method comprising:
forming the pinned magnetic layer by providing a first magnetic layer having a first magnetization, a second magnetic layer having a second magnetization, and a nonmagnetic intermediate layer sandwiched therebetween, the first magnetization being pinned in antiparallel with the second magnetization;
forming the nonmagnetic material laver;
forming the free magnetic laver;
forming a top capping layer containing tantalum on the free magnetic laver, an as-deposited thickness of the capping layer being 55 Å or more; and
performing annealing without a magnetic field in air or an inert gas flow.

7. The method for manufacturing the magnetic detection device according to claim 6, wherein the as-deposited thickness of the capping layer is 100 Å or less.

8. The method for manufacturing the magnetic detection device according to claim 6, wherein the as-deposited thickness of the capping layer is 70 to 100 Å.

9. The method for manufacturing the magnetic detection device according to claim 6, wherein the performing annealing includes:
forming a top portion of the top capping layer formed of tantalum oxide; and
forming a bottom portion of the top capping layer formed of metallic tantalum adjacent to the free magnetic layer.

10. The method for manufacturing the magnetic detection device according to claim 9, wherein the bottom portion has a thickness of at least 5 Å.

11. The method for manufacturing the magnetic detection device according to claim 9, wherein the top portion has a thickness of about 100 Å.

12. The magnetic detection device according to claim 1, wherein the capping layer includes:
a top portion formed of tantalum oxide; and
a bottom potion formed of metallic tantalum adjacent to the free magnetic layer.

13. The magnetic detection device according to claim 12, wherein the bottom portion has a thickness of at least 5 Å.

14. The magnetic detection device according to claim 12, wherein the top portion has a thickness of about 100 Å.

15. A magnetic detection device having a layered film comprising:
a self-pinned magnetic layer including:
a first magnetic layer having a first magnetization;
a second magnetic layer having a second magnetization pinned in antiparallel with the first magnetization; and
a nonmagnetic intermediate layer disposed between the first magnetic layer and the second magnetic layer;
a free magnetic layer;
a nonmagnetic material layer disposed between the self-pinned magnetic layer and the free magnetic layer; and
a top capping layer containing tantalum, formed on the free magnetic layer, the top capping layer including:
a top portion formed of tantalum oxide having a thickness of about 100 Å; and
a bottom potion formed of metallic tantalum having a thickness of at least 5 Å, the bottom portion being adjacent to the free magnetic layer.
